(19) United States
(12) Patent Application Publication
(10) Pub. No.: US 2010/0023840 A1
(43) Pub. Date: Jan. 28, 2010

(54) ECC CIRCUIT, SEMICONDUCTOR MEMORY DEVICE, MEMORY SYSTEM

(76) Inventors: Yoshiaki Nakao, Osaka (JP); Yasushi Gohou, Osaka (JP); Shunichi Iwanari, Kyoto (JP); Masanori Matsuura, Osaka (JP); Yasuo Murakuki, Kyoto (JP)

Correspondence Address: MCDERMOTT WILL & EMERY LLP, 600 13TH STREET, NW, WASHINGTON, DC, 20005-3096, US

(21) Appl. No.: 12/480,294

(22) Filed: Jun. 8, 2009

(30) Foreign Application Priority Data
Jul. 25, 2008 (JP) 2008-192321
Feb. 13, 2009 (JP) 2009-031392

(51) Int. Cl. H03M 13/05; G06F 11/10

(52) U.S. Cl. 714/763; 714/785; 714/E11.032

(57) ABSTRACT

A syndrome generation section generates a syndrome from input data having d bits of data bits and k bits of parity bits. A syndrome table stores a syndrome pattern indicating that no error has occurred in the input data and syndrome patterns indicating an error position. A comparison section compares the syndrome generated by the syndrome generation section with the syndrome patterns in the syndrome table, outputs a match signal when a syndrome pattern matching the syndrome exists, and outputs a no-match signal when no syndrome pattern matching the syndrome exists. An error correction section corrects the error in the input data based on the match signal from the comparison section.

### CROSS REFERENCE TO RELATED APPLICATIONS

This application claims priority from Japanese Patent Application No. 2008-192321, filed on Jul. 25, 2008, and Japanese Patent Application No. 2009-31392, filed on Feb. 13, 2009, each of which is hereby incorporated by reference in its entirety for all purposes.

### BACKGROUND

Technology disclosed in this specification relates to ECC circuits that perform error correction based on syndromes generated from input data, and semiconductor memory devices and memory systems that include the same.

Today, along with increase of the storage capacity of semiconductor memory devices, failure rates of memory cells incorporated into semiconductor memory devices are also increasing. Therefore, semiconductor memory devices are provided with ECC circuits, which have the capability of detecting and correcting errors in data read from memory cells.

The mechanism of error correction by these ECC circuits is generally as follows. First, an ECC circuit takes in input data, which is comprised of a combination of data bits and parity bits, then generates a syndrome (position information for identifying the error position) from the input data. Next, the ECC circuit compares the syndrome against syndrome tables. Syndrome tables respectively store a syndrome pattern indicating that no error has occurred in the input data, and syndrome patterns indicating an error position. If the comparison results in a match with the syndrome pattern indicating that no error has occurred, then the ECC circuit determines that “no error has occurred” in the input data, and outputs the data without correction. Alternatively, if a match with a syndrome pattern indicating an error position is found, the ECC circuit determines that “an error has occurred” in the input data, and corrects the error in the input data.

Japanese Unexamined Patent Application Publication (Translation of PCT Application) No. S58-501922 (referred to as “Patent Document 1”) discloses an information processing system as follows. That is, the information processing system has a plurality of syndrome tables and a data bit table for comparison with the data bits of the input data, and outputs a detect signal indicating that the input data is data whose errors cannot be corrected in cases where no match is found in all of the plurality of the syndrome tables (none of the syndrome tables have a syndrome pattern that matches the syndrome), or in cases where no match is found in some of the plurality of the syndrome tables, and no match is found in the data bit table (in the data bit table, there is no pattern that corresponds to the input data).

### SUMMARY

However, in conventional ECC circuits, one or more syndrome tables only have syndrome patterns that correspond to correctable errors among all the possible errors that can occur in the input data. This will lead to misidentification of the input data as being “error-free data” even when an error has occurred in the input data in cases where the syndrome pattern that would match the syndrome generated from the input data is not included in the syndrome table(s). This makes an error in the input data undetected (an undetected error occurs). For example, as for an ECC circuit that performs single-bit correction to 12 bits of input data that includes a combination of 8 bits of data bits and 4 bits of parity bits, the number of different syndromes that can be expressed by the parity bits (4 bits) is 16 (2⁴). On the other hand, since the number of different single-bit errors that can occur in the input data (12 bits) is 12, the syndrome table(s) has/have these 12 patterns and a single syndrome pattern which corresponds to an error-free case. This means that three syndrome patterns are not included. Thus, if an error occurs only within the parity bits in the input data and these parity bits match one of the syndrome patterns that are not included, the syndrome generated from this input data does not match any syndrome pattern in the syndrome table(s). Therefore, the input data will be output without change.

Although Patent Document 1 can prevent the aforementioned undetected errors, the need for two syndrome tables and one data table made it difficult to reduce the circuit area.

According to one aspect of the present invention, an ECC circuit includes a syndrome generation section configured to generate a syndrome from input data having d bits of data bits and k bits of parity bits (where d and k are integers greater than 1), a syndrome table storing a syndrome pattern indicating that no error has occurred in the input data and syndrome patterns indicating an error position, a comparison section configured to compare the syndrome generated by the syndrome generation section with the syndrome patterns in the syndrome table, and to output a match signal when a syndrome pattern matching the syndrome exists, and to output a no-match signal when no syndrome pattern matching the syndrome exists, and an error correction section configured to correct the error in the input data based on the match signal from the comparison section.

In the aforementioned ECC circuits, occurrence of an error in the input data can be detected by outputting a no-match signal even when the syndrome generated based on the input data is a syndrome pattern that is not included in the syndrome table. This prevents undetected errors from occurring. Moreover, since only one syndrome table is sufficient, a circuit area can be reduced as compared with conventional ones.

### BRIEF DESCRIPTION OF THE DRAWINGS

FIG. 1 is an example block diagram of a memory system in accordance with the embodiment 1.

FIG. 2 is an example block diagram of a memory system in accordance with the embodiment 2.

FIG. 3 is an example block diagram of a memory system in accordance with the embodiment 3.

FIG. 4 is an illustrative diagram of an example of a modified version of the memory system shown in FIG. 3.

### DETAILED DESCRIPTION

Example embodiments of the present invention are described below with reference to the drawings.

### Embodiment 1

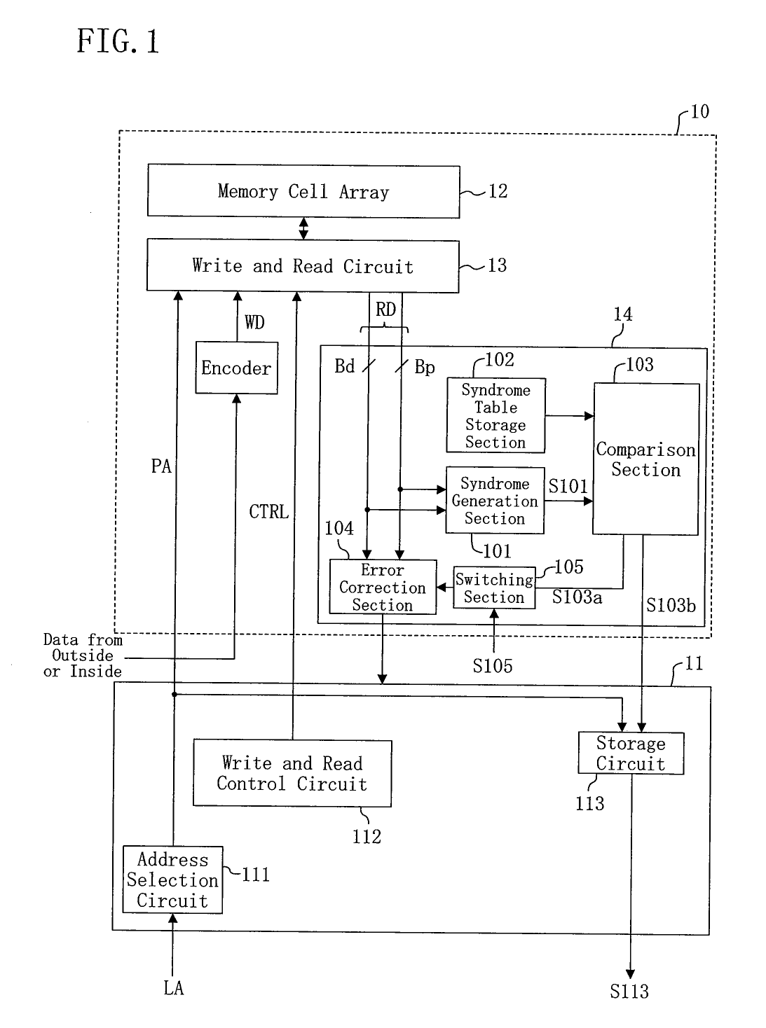

FIG. 1 illustrates an example block diagram of a memory system in accordance with the first embodiment. The memory system includes a semiconductor memory device 10 and a memory controller 11. The semiconductor memory device 10 includes a memory cell array 12 that stores data (a combination of data bits and parity bits), an encoder that encodes data from outside or inside of the semiconductor memory device 10, a write and read circuit 13 that performs data write and read operations to the memory cell array 12, and an ECC circuit 14 that performs error detection and error correction on the read data RD.

[Memory Cell Array]

The memory cell array 12 has a plurality of storage elements. For example, the memory cell array is implemented by volatile memories such as DRAMs and SRAMs, non-volatile memories such as flash memories, ferroelectric random access memories (FeRAMs), resistive random access memories (ReRAMs), magnetoresistive random access memories (MRAMs), physical fuses (fuses which can be physically disconnected), e-fuses (fuses which can be electrically disconnected), CMOS non-volatile memories (memories which use CMOS transistors), or combinations thereof.

[ECC Circuit]

The ECC circuit 14 has a syndrome generation section 101, a syndrome table storage section 102, a comparison section 103, an error correction section 104, and a switching section 105. The syndrome generation section 101 generates a syndrome S101 from the data RD read from the memory cell array 12. The data RD is (d+k) bits of data, which includes d bits of bit data Bd and k bits of parity bits Bp (where d and k are integers greater than 1). The syndrome table storage section 102 stores a syndrome pattern indicating that no error has occurred in the data RD, and syndrome patterns indicating an error position. The comparison section 103 compares the syndrome S101 generated by the syndrome generation section 101 with the syndrome patterns in the syndrome table stored in the syndrome table storage section 102, then outputs a match signal S103a when a syndrome pattern matching the syndrome S101 exists in the syndrome table, and outputs a no-match signal S103b when no syndrome pattern matching the syndrome S101 exists. When the match signal S103a is delivered, the error correction section 104 corrects the error in the data RD based on the match signal S103a. In response to the externally provided control signal S105, the switching section 105 switches between a pass-through mode, where the match signal S103a from the comparison section 103 is delivered to the error correction section 104, and a blocking mode, where the match signal S103a from the comparison section 103 is not delivered to the error correction section 104.

[Memory Controller]

The memory controller 11 has an address selection circuit 111, a write and read control circuit 112, and a storage circuit 113. The address selection circuit 111 stores one or more address tables, in which logical addresses are associated with physical addresses of the memory cell array 12. The address selection circuit 111 also selects a physical address PA corresponding to an externally provided logical address LA by referring to the address table(s). The write and read control circuit 112 controls write and read operations performed by the write and read circuit 13. The storage circuit 113 has a rewritable memory cell array. In the storage circuit 113, all the physical addresses of the memory cell array 12 are registered. For example, after power-up, an address read operation in which all of the addresses of the memory cell array 12 are read is performed in order to register all the physical addresses of the memory cell array 12 in the storage circuit 113. Note that if the memory cell array of the storage circuit 113 is an array of non-volatile memories, no address read operation is required because the information can be retained after power-down. The storage circuit 113 also stores the comparison results by the comparison section 103 (information on whether a no-match signal S103b has been output or not) for each of the registered physical addresses of the memory cell array 12. Furthermore, the storage circuit 113 outputs an error detect signal S113 after storing the comparison result indicating that a no-match signal S103b has been output.

[Operation]

Now, a data write operation of the memory system shown in FIG. 1 is described.

First, the address selection circuit 111 selects the physical address PA corresponding to the logical address LA. The write and read control circuit 112 outputs a control signal CTRL, thereby controlling the operation of the write and read circuit 13. In response to the control signal CTRL from the write and read control circuit 112, the write and read circuit 13 writes data WD encoded by the encoder to the physical address in the memory cell array 12 selected by the address selection circuit 111 (write operation).

Next, after completion of the write operation of the data WD, in response to the control signal CTRL, the write and read circuit 13 reads data from the physical address in the memory cell array 12 selected by the address selection circuit 111 (verify operation). That is, the written data WD is read out as the data RD.

Then, in the ECC circuit 14, the syndrome generation section 101 generates a syndrome S101 from the data RD, and the comparison section 103 compares the syndrome S101 with the syndrome patterns in the syndrome table.

Next, the storage circuit 113 stores the comparison result by the comparison section 103 in connection with the physical address selected by the address selection circuit 111 from the previously registered physical addresses, and outputs an error detect signal S113.

As described above, according to this embodiment, outputting of an error detect signal S113 allows for detection of occurrence of errors in the data RD for any error occurred in the data RD. This prevents undetected errors from occurring. Moreover, since only one syndrome table is sufficient, a circuit area can be reduced as compared with conventional ones (Patent Document 1).

It is also possible to provide users with the error detect signal S113 as a “lifetime indication signal.” This enables users to know the time limit for using the memory system more easily, and to backup the data stored in the semiconductor memory device 10 to another memory device.

Furthermore, the control ability of the switching section 105 over the delivery of the match signal S103a allows the error correction section 104 not to perform error correction operations as necessary. This accelerates the read operation of the data RD when no error correction is required. Note that the match signal S103a from the comparison section 103 may be delivered to the error correction section 104 without passing through the switching section 105.

### Embodiment 2

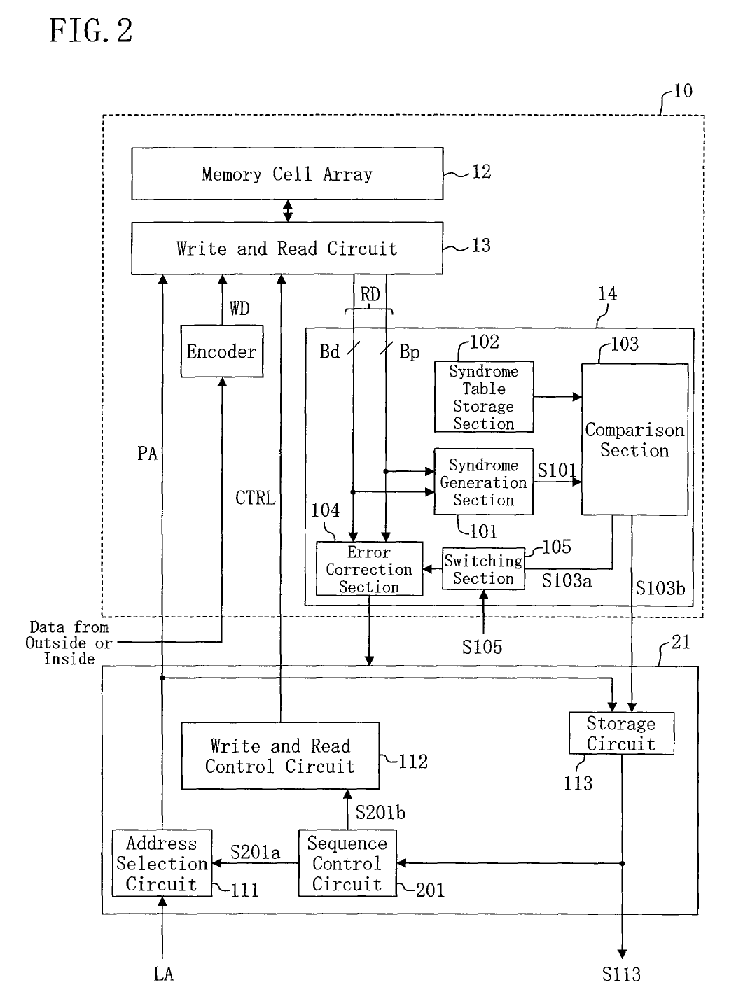

FIG. 2 illustrates an example block diagram of a memory system in accordance with the second embodiment. In this memory system, the memory controller 21 further includes a sequence control circuit 201 in addition to those shown in FIG. 1. In response to the error detect signal S113 from the storage circuit 113, the sequence control circuit 201 outputs an address change signal S201a for modifying the address table(s) stored in the address selection circuit 111, and a write instruction signal S201b for controlling the operation of the write and read control circuit 112.

[Operation]

Now, a write sequence control by the sequence control circuit 201 shown in FIG. 2 is described.

First, as in the embodiment 1, the write and read circuit 13 performs write and verify operations to the physical address in the memory cell array 12 selected by the address selection circuit 111.

At this stage, if the comparison section 103 outputs a no-match signal S103b, the storage circuit 113 outputs an error detect signal S113. When an error detect signal S113 is output, the sequence control circuit 201 outputs an address change signal S201a and modifies the address table(s) so that the current logical address is associated with a different physical address. Thus, the physical address selected by the address selection circuit 111 is changed.

Then, the sequence control circuit 201 outputs a write instruction signal S201b. In response to the write instruction signal S201b, the write and read control circuit 112 commands the write and read circuit 13 to perform the write and verify operations again. This causes the write and read circuit 13 to perform the write and verify operations to the different physical address (the physical address after the change) of the memory cell array 12.

As described above, outputting of a no-match signal S103b causes the physical address to be changed, thereby allowing for control so that the data WD will not be written into an address area whose errors cannot be corrected in the memory cell array 12. This allows the address area whose errors cannot be corrected to be excluded from the scope of use.

### Embodiment 3

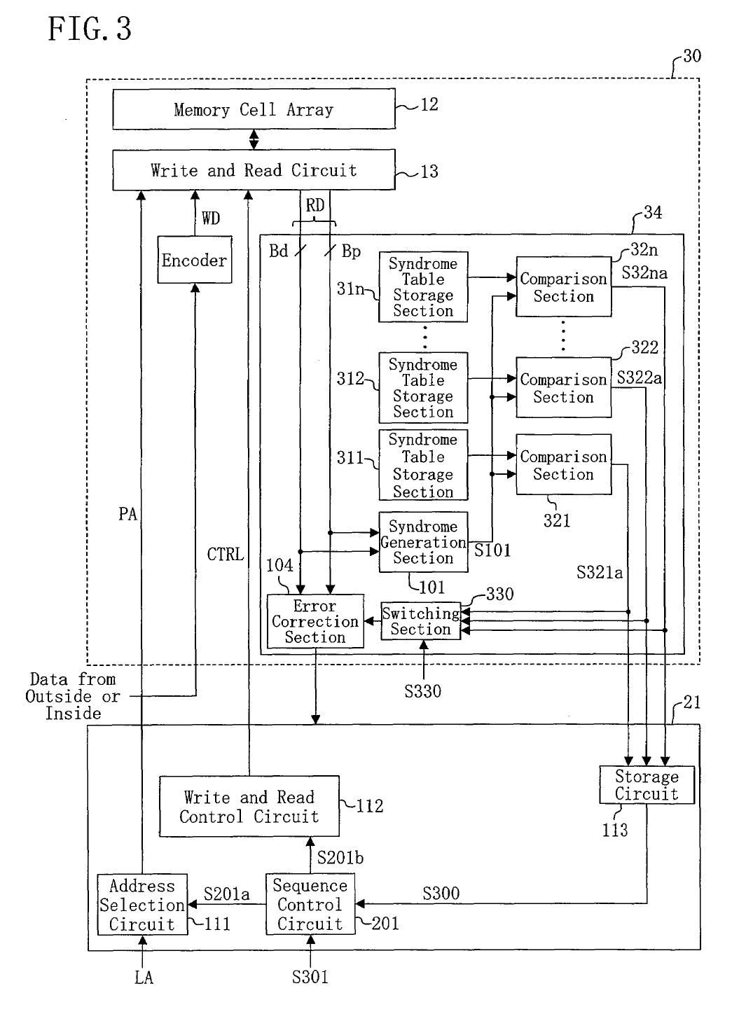

FIG. 3 illustrates an example block diagram of a memory system in accordance with the third embodiment. In this memory system, the semiconductor memory device 30 includes an ECC circuit 34 instead of the ECC circuit 14 shown in FIG. 2. The ECC circuit 34 includes n (n is an integer greater than 1) syndrome table storage sections 311, 312, . . . , and 31n, n comparison sections 321, 322, . . . , and 32n, and a selection section 330, instead of the syndrome table storage section 102, the comparison section 103, and the switching section 105 shown in FIG. 1. The other structure is the same as shown in FIG. 2.

The n syndrome table storage sections 311, 312, . . . , and 31n have, respectively, syndrome tables that correspond to a different number of error bits. For example, the first, second, . . . , and nth syndrome table storage sections 311, 312, . . . , and 31n have, respectively, syndrome tables that correspond to single-bit errors, double-bit errors, . . . , and n-bit errors. The n comparison sections 321, 322, . . . , and 32n, respectively, correspond to the n syndrome table storage sections 311, 312, . . . , and 31n, compare the syndrome S101 generated by the syndrome generation section 101 with the syndrome patterns in the syndrome table stored in the syndrome table storage section that corresponds to the comparison section itself, and, if a syndrome pattern matching the syndrome S101 exists in the syndrome table, output match signals S321a, S322a, . . . , and S32na. In response to an externally provided control signal S330, the selection section 330 delivers one of the match signals S321a, S322a, . . . , and S32na from the comparison sections 321, 322, . . . , and 32n to the error correction section 104.

The error correction section 104 corrects the error in the data RD based on the match signal that has been selected by the selection section 330 from the match signals S321a, S322a, . . . , and S32na. For example, the error correction section 104 performs single-bit correction upon delivery of the match signal S321a, and double-bit correction upon delivery of the match signal S322a. The storage circuit 113 stores the number of error bits corresponding to the output states of the match signals S321a, S322a, . . . , and S32na for each physical address. For example, when only the match signal S321a is output, the storage circuit 113 stores the number of error bits as “one bit.” The storage circuit 113 also outputs an error notification signal S300 that indicates the number of error bits corresponding to the physical address PA selected by the address selection circuit 111, to the sequence control circuit 201. The sequence control circuit 201 outputs an address change signal S201a and a write instruction signal S201b based on the error notification signal S300 and an externally provided selection signal S301. The selection signal S301 indicates the number of error bits allowed for the address area where the write data WD is written.

[Operation]

Now, a data write operation of the memory system shown in FIG. 3 is described.

First, as in the embodiment 2, the write and read circuit 13 performs write and verify operations to the physical address in the memory cell array 12 selected by the address selection circuit 111.

Then, the storage circuit 113 stores the number of error bits corresponding to the output states of the match signals S321a, S322a, . . . , and S32na in connection with the physical address selected by the address selection circuit 111 from the previously registered physical addresses. Next, the storage circuit 113 outputs an error notification signal S300 that indicates the number of error bits.

Then, when the numbers of error bits indicated respectively in the error notification signal S300 and the selection signal S301 do not match each other, the sequence control circuit 201 outputs an address change signal S201a and a write instruction signal S201b. This changes the physical address corresponding to the logical address, thus allowing the write and verify operations to be performed to the physical address after the change in the memory cell array 12. Alternatively, when the numbers of error bits indicated respectively in the error notification signal S300 and the selection signal S301 match each other, the sequence control circuit 201 does not output either an address change signal S201a or a write instruction signal S201b.

As described above, by changing the physical address when the numbers of error bits indicated respectively in the error notification signal S300 and the selection signal S301 do not match each other, the address area in the memory cell array 12 where the data WD is written can be selected based on the number of error bits. This allows high priority data to be stored in the most reliable address area (the address area with the smallest number of error bits), thus reducing the risk of data loss due to aging degradation.

Moreover, due to selective delivery of the match signals S321a, S322a, . . . , and S32na to the error correction section 104 by the selection section 330, the error correction ability of the error correction section 104 can be set as desired. Note that the match signals S321a, S322a, . . . , and S32na may be delivered to the error correction section 104 without passing through the selection section 330.

### An Example of a Modified Version of the Embodiment 3

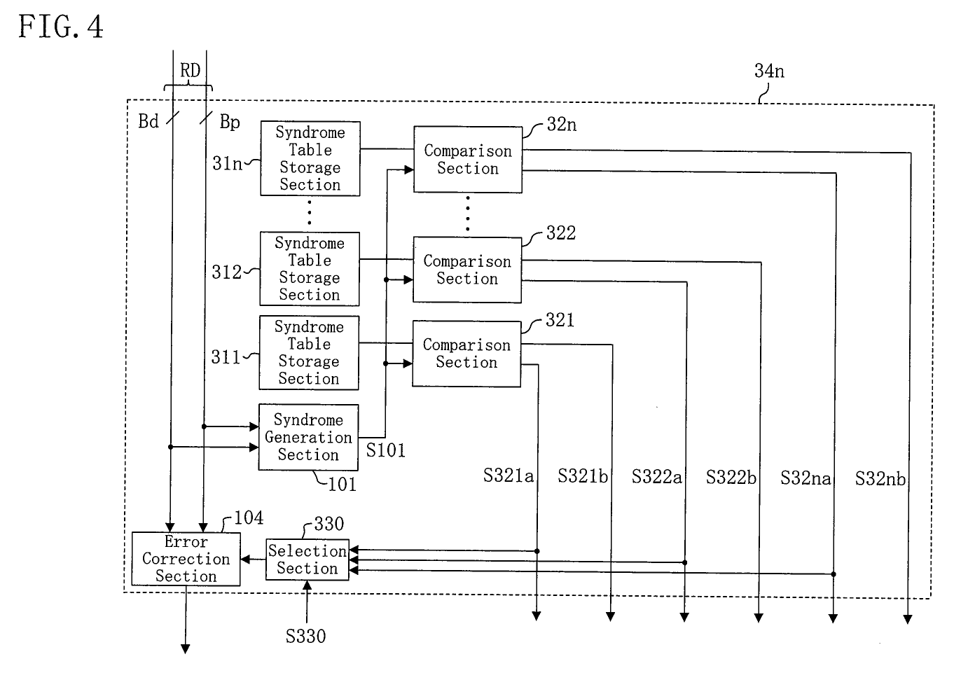

The ECC circuit shown in FIG. 3 may be replaced with an ECC circuit shown in FIG. 4. In the ECC circuit 34n shown in FIG. 4, the n comparison sections 321, 322, . . . , and 32n compare the syndrome S101, respectively, with the syndrome patterns stored in the syndrome table storage section that corresponds to the comparison section itself, and, if no syndrome pattern matching the syndrome S101 exists, output no-match signals S321b, S322b, . . . , and S32nb. The storage circuit 113 stores the output patterns of the no-match signals S321b, S322b, . . . , and S32nb for each physical address. This structure allows the no-match signals S321b, S322b, . . . , and S32nb to be output as “lifetime indication signals.” This enables users to know the time limit for using the memory system more easily.

The described ECC circuits, semiconductor memory devices, and memory systems are useful, for example, for products with respect to data communication, reproduction devices for storage media such as CDs and DVDs, and products that incorporate semiconductor memory devices such as memory sticks and integrated circuit (IC) cards.

1. An ECC circuit comprising:
a syndrome generation section configured to generate a syndrome from input data having d bits of data bits and k bits of parity bits (where d and k are integers greater than 1);
a syndrome table, where the syndrome table stores a syndrome pattern indicating that no error has occurred in the input data, and syndrome patterns indicating an error position;
a comparison section configured to compare the syndrome generated by the syndrome generation section with the syndrome patterns in the syndrome table, to output a match signal when a syndrome pattern matching the syndrome exists, and to output a no-match signal when no syndrome pattern matching the syndrome exists; and
an error correction section configured to correct the error in the input data based on the match signal from the comparison section.

2. An ECC circuit of claim 1, further comprising:
a switching section having a capability of switching between a delivery mode, where the match signal from the comparison section is delivered to the error correction section, and a blocking mode, where the match signal from the comparison section is not delivered to the error correction section.

3. A semiconductor memory device comprising:
an ECC circuit of claim 1;
a memory cell array; and
a write and read circuit configured to, in a write operation, write data to the memory cell array and, in a read operation, read and deliver the data stored in the memory cell array to the ECC circuit.

4. A memory system comprising:
a semiconductor memory device of claim 3; and
a memory controller having an address selection circuit and a control circuit,
wherein
the address selection circuit selects a physical address corresponding to an externally provided logical address based on one or more address tables, in which logical addresses are associated with physical addresses of the memory cell array,
the write and read circuit performs a write operation to write data to the physical address in the memory cell array selected by the address selection circuit, and a verify operation to read and deliver the data written to the physical address to the ECC circuit, and
the control circuit, when the no-match signal is output from the comparison section, changes the one or more address tables, and then commands the write and read circuit to perform the write and the verify operations again.

5. An ECC circuit comprising:
a syndrome generation section configured to generate a syndrome from input data having d bits of data bits and k bits of parity bits (where d and k are integers greater than 1);
syndrome tables corresponding respectively to a different number of error bits, where the syndrome tables respectively store a syndrome pattern indicating that no error has occurred in the input data and syndrome patterns indicating an error position;
a plurality of comparison sections, corresponding respectively to the plurality of syndrome tables, configured to compare the syndrome generated by the syndrome generation section with the syndrome patterns in the syndrome table that corresponds to the comparison section itself, and, when a syndrome pattern matching the syndrome exists, output match signals; and
an error correction section configured to correct the error in the input data based on the match signals from the plurality of comparison sections.

6. An ECC circuit of claim 5, wherein the plurality of comparison sections respectively output no-match signals when no syndrome pattern matching the syndrome generated by the syndrome generation section exists in the syndrome table that corresponds to the comparison section itself.

7. An ECC circuit of claim 5 further comprising:
a selection circuit configured to be provided with the plurality of match signals from the plurality of comparison sections, and to deliver one of the plurality of match signals to the error correction section.

8. A semiconductor memory device comprising:
an ECC circuit of claim 5;
a memory cell array; and
a write and read circuit configured to, in a write operation, write data to the memory cell array and, in a read operation, read and deliver the data stored in the memory cell array to the ECC circuit.

9. A memory system comprising:
a semiconductor memory device of claim 8; and
a memory controller having an address selection circuit and a control circuit,
wherein
the address selection circuit selects a physical address corresponding to an externally provided logical address based on one or more address tables, in which logical addresses are associated with physical addresses of the memory cell array,
the write and read circuit performs a write operation to write data to the physical address in the memory cell array selected by the address selection circuit, and a verify operation to read and deliver the data written to the physical address to the ECC circuit, and
the control circuit, when the number of error bits corresponding to the comparison section that output the match signal among the plurality of comparison sections does not match a previously set desired number of error bits, changes the one or more address tables, and then commands the write and read circuit to perform the write and the verify operations again.

10. A memory system of claim 4, wherein the memory cell array is comprised of non-volatile memories.

11. A memory system of claim 9, wherein the memory cell array is comprised of non-volatile memories.

12. A memory system of claim 10, wherein the non-volatile memories are comprised of ferroelectric material.

13. A memory system of claim 11, wherein the non-volatile memories are comprised of ferroelectric material.
